(19) United States
(12) Patent Application Publication
(10) Pub. No.: US 2025/0260496 A1
(43) Pub. Date: Aug. 14, 2025

(54) MOBILE TERMINAL TESTING DEVICE AND MOBILE TERMINAL TESTING METHOD

(71) Applicant: ANRITSU CORPORATION, Kanagawa (JP)

(72) Inventors: Hideyuki ENDO, Kanagawa (JP); Akihito YOSHITO, Kanagawa (JP); Keisuke SUZUKI, Kanagawa (JP); Atsuya HATANO, Kanagawa (JP)

(21) Appl. No.: 19/035,050

(22) Filed: Jan. 23, 2025

(30) Foreign Application Priority Data
Feb. 8, 2024 (JP) 2024-017864

(51) Int. Cl. H04B 17/15; G01R 29/08; H04B 17/10

(52) U.S. Cl. CPC H04B 17/191; G01R 29/0821; G01R 29/0871; H04B 17/102

(57) ABSTRACT

There is provided a mobile terminal testing device that can improve the accuracy of measurement results. A reference position measurement control unit 18c that measures output power of a DUT 100 at a Reference position, which is any preset measurement position, each time a certain period of time elapses in a case where a total spherical scanning of the DUT 100 is performed, and that, in a case where the output power is equal to or less than a preset regulated Power, interrupts the measurement, excludes measurement data after the previous measurement at a Reference position from the measured value, and enables the measurement to be resumed from the excluded measurement position is provided.

### TECHNICAL FIELD

The present invention relates to a mobile terminal testing device that tests a mobile terminal by exchanging signals while changing an angle of a positioner on which the mobile terminal is installed under an Over The Air (OTA) environment.

### BACKGROUND ART

For a wireless terminal that has been developed in recent years and transmits and receives a radio signal corresponding to IEEE802.11ad, 5G cellular, and the like, in which a signal in a wide band of a millimeter wave band is used, a performance test is performed of measuring an output level and reception sensitivity of a transmitted radio wave determined for each communication standard with respect to a wireless communication antenna included in the wireless terminal, and determining whether or not a predetermined reference is satisfied.

For example, in a performance test in which a wireless terminal (hereinafter, referred to as a “5G wireless terminal”) for a New Radio System (NR system) of a fifth generation mobile communication system (hereinafter, also referred to as “5G”) is used as a Device Under Test (DUT), an OTA test using an anechoic box (OTA chamber) referred to as a Compact Antenna Test Range (CATR) that is not affected by a surrounding radio wave environment is performed.

As an example of a wireless terminal measurement device according to the related art capable of performing an OTA test, it is known that a wireless terminal is rotated around a reference point in a measurement space such as an anechoic box or an anechoic chamber, while radio waves transmitted from the wireless terminal are received by a measurement antenna, and radiation power characteristics (such as Equivalent Isotropic Radiated Power (EIRP), Equivalent Isotropic Sensitivity (EIS), Total Radiated Power (TRP)) of the wireless terminal are obtained from the received signal.

Patent Document 1 describes that, in the measurement of the DUT that is rotated to sequentially face all orientations of the spherical coordinate system under the OTA environment, the progress of the measurement at each measurement position is displayed.

### RELATED ART DOCUMENT

### Patent Document

[Patent Document 1] Japanese Patent No. 7227198

### DISCLOSURE OF THE INVENTION

### Problem That the Invention is to Solve

In measurements in the OTA environment, there are many time-consuming measurements such as a spherical coverage measurement, and in a case where the DUT generates heat due to the DUT continuously outputting the maximum power, the DUT may intentionally reduce the output in order to protect the DUT. In addition, the same phenomenon occurs even in a case where the remaining battery level decreases due to the long-time call connection.

Since these phenomena are not desirable measurement results that indicate the actual capabilities of the DUT, there is a demand to exclude these phenomena.

Therefore, an object of the present invention is to provide a mobile terminal testing device that can improve the accuracy of measurement results by excluding measurement data in which the output of the DUT is considered to be reduced.

### Means for Solving The Problem

According to the present invention, there is provided a mobile terminal testing device of the present invention including: a positioner that is provided in an internal space of an anechoic box, has an azimuth axis and a roll axis that are each rotationally drivable by a drive motor, and rotates a mobile terminal that is a device under test so that the mobile terminal sequentially faces a plurality of preset angular sample points of a spherical coordinate system, using a center of the spherical coordinate system as a reference point; a simulated measurement device connected to a test antenna in the internal space; an integrated control device that controls the simulated measurement device so that a measurement operation of transmitting a test signal from the test antenna to the mobile terminal, receiving a signal under measurement transmitted from the mobile terminal that has received the test signal by using the test antenna, and measuring a specific measurement item related to the mobile terminal based on the received signal under measurement is performed at a measurement position corresponding to each of the plurality of angular sample points; and a Reference position measurement control unit that measures output power of the mobile terminal at a preset Reference position each time a preset regulated time elapses, and that, in a case where the measured output power is equal to or less than a preset regulated Power, interrupts the measurement, excludes measurement data after the measurement at a previous Reference position from a measured value, and enables the measurement to be resumed from the excluded measurement position.

With this configuration, the output power of the mobile terminal at the Reference position is measured each time the regulated time elapses, and in a case where the measured output power is equal to or less than the regulated power, the measurement is interrupted, the measurement data after the previous measurement at the Reference position is excluded from the measured value, and the measurement is resumable from the excluded measurement position. Therefore, it is possible to improve the accuracy of measurement results by excluding the measurement data in which the output of the DUT is considered to be reduced.

In addition, according to the present invention, there is provided a mobile terminal testing method of a mobile terminal testing device including a positioner that is provided in an internal space of an anechoic box, has an azimuth axis and a roll axis that are each rotationally drivable by a drive motor, and rotates a mobile terminal that is a device under test so that the mobile terminal sequentially faces a plurality of preset angular sample points of a spherical coordinate system, using a center of the spherical coordinate system as a reference point, a simulated measurement device connected to a test antenna in the internal space, and an integrated control device that controls the simulated measurement device so that a measurement operation of transmitting a test signal from the test antenna to the mobile terminal, receiving a signal under measurement transmitted from the mobile terminal that has received the test signal by using the test antenna, and measuring a specific measurement item related to the mobile terminal based on the received signal under measurement is performed at a measurement position corresponding to each of the plurality of angular sample points, the mobile terminal testing method including: a step of measuring output power of the mobile terminal at a preset Reference position each time a preset regulated time elapses, and a step of interrupting the measurement, excluding measurement data after the measurement at a previous Reference position from a measured value, and enabling the measurement to be resumed from the excluded measurement position, in a case where the measured output power is equal to or less than a preset regulated Power.

With this configuration, the output power of the mobile terminal at the Reference position is measured each time the regulated time elapses, and in a case where the measured output power is equal to or less than the regulated power, the measurement is interrupted, the measurement data after the previous measurement at the Reference position is excluded from the measured value, and the measurement is resumable from the excluded measurement position. Therefore, it is possible to improve the accuracy of measurement results by excluding the measurement data in which the output of the DUT is considered to be reduced.

### Advantage of the Invention

The present invention can provide a mobile terminal testing device that can improve the accuracy of measurement results.

### BRIEF DESCRIPTION OF THE DRAWINGS

FIG. 1 is a diagram showing a schematic configuration of an entire measurement device according to an embodiment of the present invention.

FIG. 2 is a block diagram showing a functional configuration of the measurement device according to the embodiment of the present invention.

FIG. 3 is a block diagram showing functional configurations of an integrated control device of the measurement device and a controlled system element thereof according to the embodiment of the present invention.

FIG. 4 is a block diagram showing a functional configuration of an NR system simulator in the measurement device according to the embodiment of the present invention.

FIGS. 5A and 5B are diagrams showing total spherical scanning images of a device under test in an OTA chamber of the measurement device according to the embodiment of the present invention, in which FIG. 5A shows a disposition mode of the device under test with respect to a center of a spherical coordinate system, and FIG. 5B shows a distribution mode of angular sample points PS in the spherical coordinate system.

FIG. 6 is a diagram explaining a disposition mode of a test antenna 5 in the OTA chamber of the measurement device according to the embodiment of the present invention using the spherical coordinate system (r, θ, φ) shown in FIGS. 5A and 5B.

FIG. 7 is a diagram showing a rotation drive image around an azimuth axis and a roll axis of a biaxial positioner related to the total spherical scanning of the DUT in the measurement device according to the embodiment of the present invention.

FIG. 8 is a flowchart showing a procedure of a measurement control operation of the measurement device according to the embodiment of the present invention.

### BEST MODE FOR CARRYING OUT THE INVENTION

Hereinafter, a measurement device as a mobile terminal testing device according to an embodiment of the present invention will be described with reference to the drawings.

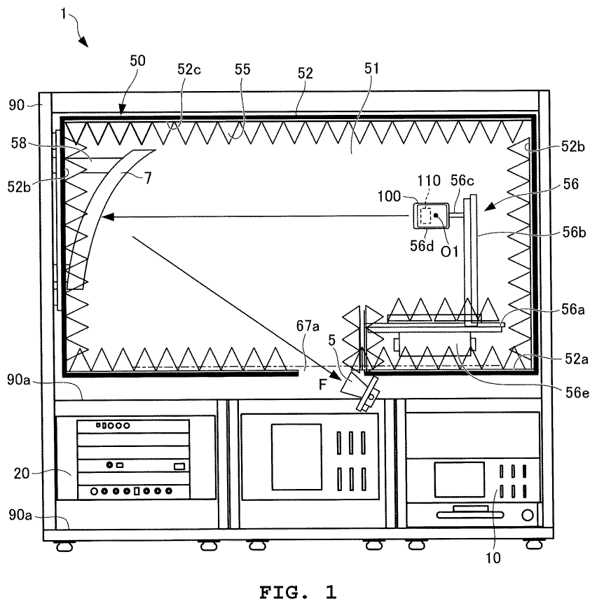

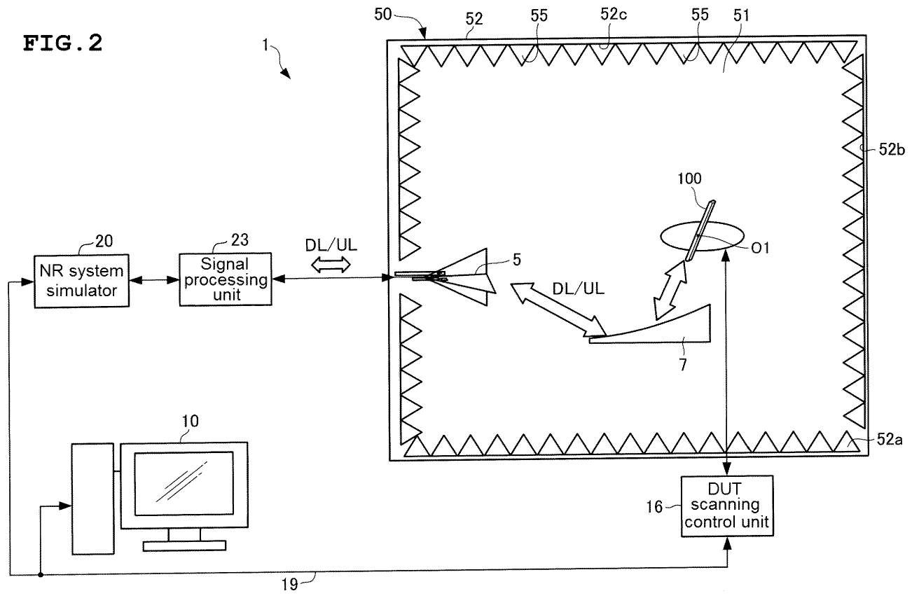

First, a configuration of a measurement device 1 according to the embodiment of the present invention will be described with reference to FIGS. 1 to 4. The measurement device 1 constitutes the mobile terminal testing device of the present invention. The measurement device 1 according to the present embodiment has an external structure as shown in FIG. 1 as a whole, and includes functional blocks as shown in FIG. 2. FIGS. 1 and 2 show a disposition mode of each component of an OTA chamber 50 in a state of being seen through from a side surface thereof.

The measurement device 1 is operated, for example, in a mode in which each of the above-described components is mounted on each rack 90a of a rack structure 90 having the structure shown in FIG. 1. FIG. 1 shows an example in which each of an integrated control device 10, an NR system simulator 20, and an OTA chamber 50 is mounted on each rack 90a of the rack structure 90.

As shown in FIG. 2, the measurement device 1 includes the integrated control device 10, the NR system simulator 20, a signal processing unit 23, and the OTA chamber 50.

For the configuration, the OTA chamber 50 will be described first. As shown in FIGS. 1 and 2, the OTA chamber 50 includes, for example, a metal housing main body 52 having a rectangular internal space 51, and accommodates a DUT 100 having an antenna 110, a test antenna 5, a reflector 7, and a DUT scanning mechanism 56 in the internal space 51.

A radio wave absorber 55 is attached to a whole area of an inner surface of the OTA chamber 50, that is, a bottom surface 52a, a side surface 52b, and a top surface 52c of the housing main body 52. As a result, in the OTA chamber 50, each element (the DUT 100, the test antenna 5, the reflector 7, and the DUT scanning mechanism 56) disposed in the internal space 51 has an enhanced function of regulating intrusion of radio waves from the outside and radiation of the radio waves to the outside. In this way, the OTA chamber 50 realizes an anechoic box having the internal space 51 that is not affected by a surrounding radio wave environment. The anechoic box used in the present embodiment is, for example, an anechoic type.

Among those accommodated in the internal space 51 of the OTA chamber 50, the DUT 100 is, for example, a wireless terminal such as a smartphone. Communication standards for the DUT 100 include cellular (LTE, LTE-A, W-CDMA (registered trademark), GSM (registered trademark), CDMA 2000, 1xEV-DO, TD-SCDMA, or the like), wireless LAN (IEEE 802.11b/g/a/n/ac/ad, or the like), Bluetooth (registered trademark), GNSS (GPS, Galileo, GLONASS, BeiDou, or the like), FM, and digital broadcasting (DVB-H, ISDB-T, or the like). Further, the DUT 100 may be a wireless terminal that transmits and receives a radio signal in a millimeter wave band corresponding to IEEE 802.11ad, 5G cellular, or the like.

In the present embodiment, the antenna 110 of the DUT 100 uses a radio signal in each regulated frequency band in conformity with, for example, LTE or 5G NR communication standard. The DUT 100 constitutes the device under test, that is, a mobile terminal in the present invention.

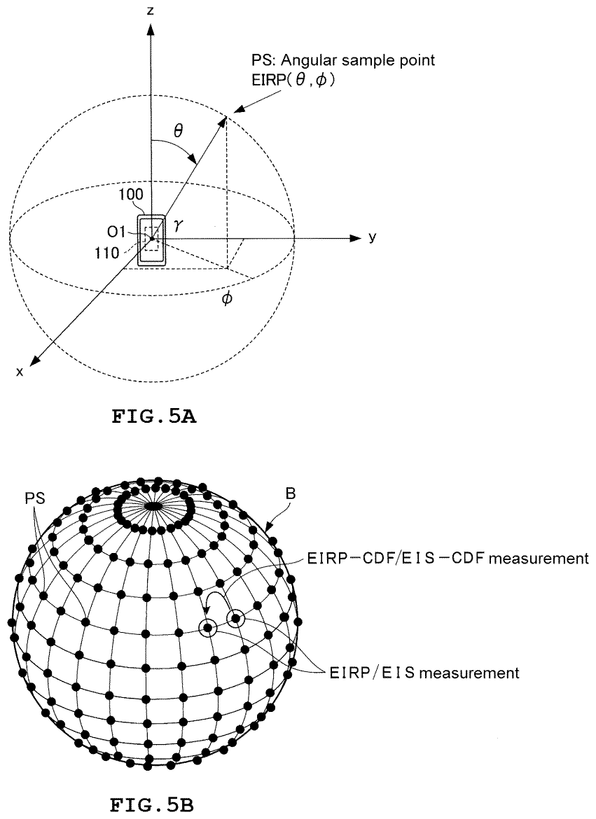

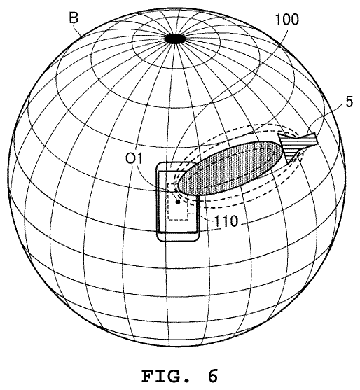

In the internal space 51 of the OTA chamber 50, the DUT 100 is held by a part of mechanism of the DUT scanning mechanism 56. The DUT scanning mechanism 56 is provided to extend in a vertical direction on the bottom surface 52a of the housing main body 52 in the internal space 51 of the OTA chamber 50. The DUT scanning mechanism 56 performs a total spherical scanning (refer to FIGS. 5A and 5B and FIG. 6), which will be described later, on the DUT 100 while holding the DUT 100 on which a performance test is performed.

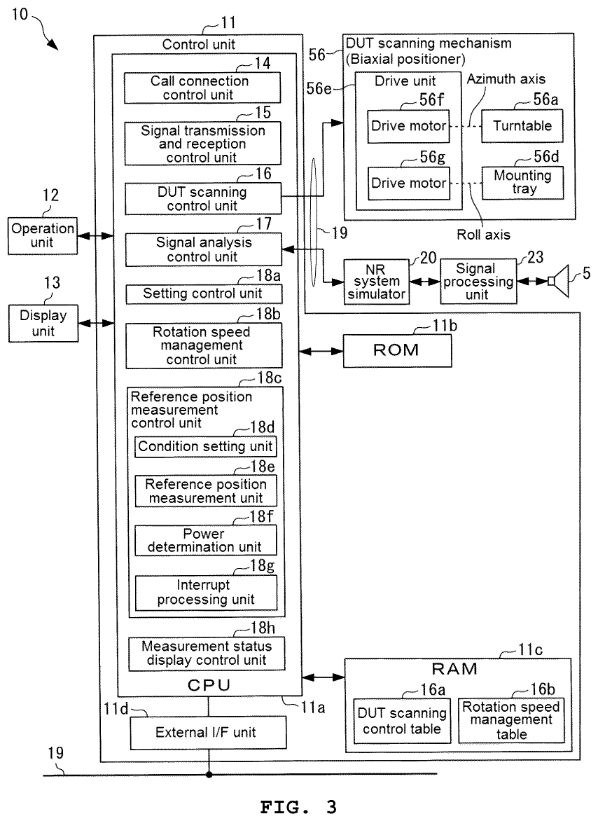

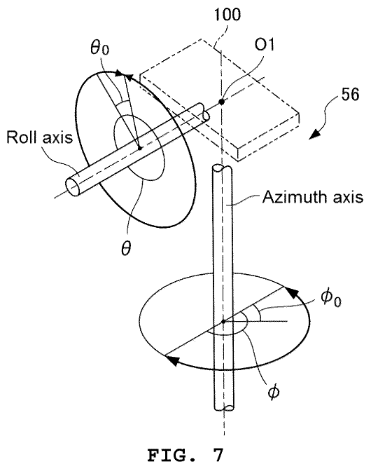

As shown in FIG. 1, the DUT scanning mechanism 56 includes a turntable 56a, a support column member 56b, a DUT mounting portion 56c, and a drive unit 56e. The turntable 56a includes a plate member having a disk shape, and has a configuration (refer to FIG. 3 and FIG. 7) that rotates around an azimuth axis (a rotation axis in the vertical direction). The support column member 56b includes a columnar member disposed to extend in a direction perpendicular to a plate surface of the turntable 56a.

The DUT mounting portion 56c is disposed near an upper end of the support column member 56b to be in parallel with the turntable 56a, and has a mounting tray 56d on which the DUT 100 is mounted. The DUT mounting portion 56c has a configuration (refer to FIG. 3 and FIG. 7) capable of rotating around a roll axis (a rotation axis in a horizontal direction).

As shown in FIG. 3, the drive unit 56e includes, for example, a drive motor 56f that rotationally drives the azimuth axis, and a drive motor 56g that rotationally drives the roll axis. The drive unit 56e includes a biaxial positioner provided with a mechanism for performing rotations around the azimuth axis and the roll axis, respectively, by the drive motor 56f and the drive motor 56g. In this way, the drive unit 56e can rotate the DUT 100 mounted on the mounting tray 56d in biaxial (the azimuth axis and the roll axis) directions for each mounting tray 56d. Hereinafter, there is a case where the entire DUT scanning mechanism 56 including the drive unit 56e is referred to as the biaxial positioner (refer to FIG. 3).

The DUT scanning mechanism (biaxial positioner) 56 performs total spherical scanning which sequentially changes a posture of the DUT 100 in a state in which the antenna 110 faces all orientations (a plurality of preset orientations) of a surface of the sphere while assuming that the DUT 100 mounted (held) on the mounting tray 56d is disposed, for example, at a center O1 of a sphere (refer to a sphere B in FIGS. 5A and 5B). Control of the DUT scanning in the DUT scanning mechanism 56 is performed by a DUT scanning control unit 16 which will be described later. The DUT scanning mechanism 56 constitutes the positioner in the present invention.

The test antenna 5 is attached to a required position on the bottom surface 52a of the housing main body 52 of the OTA chamber 50 by using an appropriate holder (not shown). An attachment position of the test antenna 5 is a position at which visibility can be secured from the reflector 7 via an opening 67a provided on the bottom surface 52a. The test antenna 5 uses a radio signal in the frequency band of the same regulation (NR standard) as the antenna 110 of the DUT 100.

In a case where measurement related to the NR of the DUT 100 is performed in the OTA chamber 50, the test antenna 5 transmits a test signal from the NR system simulator 20 to the DUT 100 and receives a signal under measurement transmitted from the DUT 100 that has received the test signal. The test antenna 5 is disposed so that a light reception surface thereof becomes a focal position F of the reflector 7. The reflector 7 is not always required in a case where the test antenna 5 can be disposed so that the light reception surface thereof faces the DUT 100 and appropriate light reception can be performed.

The reflector 7 is attached to a required position on the side surface 52b of the OTA chamber 50 by using a reflector holder 58. The reflector 7 realizes a radio wave path that returns the radio signal (the test signal and the signal under measurement) transmitted and received by the antenna 110 of the DUT 100 to the light reception surface of the test antenna 5.

Subsequently, configurations of the integrated control device 10 and the NR system simulator 20 will be described.

As shown in FIG. 2, the integrated control device 10 is communicably connected to the NR system simulator 20 via a network 19 such as Ethernet (registered trademark). Further, the integrated control device 10 is also connected to a controlled system element in the OTA chamber 50, for example, the DUT scanning control unit 16 via the network 19.

The integrated control device 10 comprehensively controls the NR system simulator 20 and the DUT scanning control unit 16 via the network 19, and includes, for example, a Personal Computer (PC). The DUT scanning control unit 16 may be independently provided accompanying with the OTA chamber 50 (refer to FIG. 2), or may be provided in the integrated control device 10 as shown in FIG. 3. Hereinafter, description will be performed while assuming that the integrated control device 10 has the configuration shown in FIG. 3.

As shown in FIG. 3, the integrated control device 10 includes a control unit 11, an operation unit 12, and a display unit 13. The control unit 11 includes, for example, a computer device. The computer device includes a Central Processing Unit (CPU) 11a that performs predetermined information processing to realize the function of the measurement device 1, and performs comprehensive control on the NR system simulator 20, and the DUT scanning control unit 16 as targets, a Read Only Memory (ROM) 11b that stores an Operating System (OS) for starting up the CPU 11a, the other programs, and control parameters, and the like, a Random Access Memory (RAM) 11c that stores execution code, data, and the like of the OS or an application which is used for an operation by the CPU 11a, an external I/F unit 11d, an input and output port (not shown), and the like.

The external I/F unit 11d is communicably connected to each of the NR system simulator 20 and the drive unit 56e of the DUT scanning mechanism (biaxial positioner) 56 via the network 19. An operation unit 12 and a display unit 13 are connected to the input and output port. The operation unit 12 is a functional unit for inputting various information such as commands, and the display unit 13 is a functional unit for displaying various information such as an input screen, measurement results, and the like of the various information.

The computer device described above functions as the control unit 11 in such a way that the CPU 11a executes a program stored in the ROM 11b while using the RAM 11c as a work area. As shown in FIG. 3, the control unit 11 includes a call connection control unit 14, a signal transmission and reception control unit 15, a DUT scanning control unit 16, a signal analysis control unit 17, a setting control unit 18a, a rotation speed management control unit 18b, a Reference position measurement control unit 18c, and a measurement status display control unit 18h. The call connection control unit 14, the signal transmission and reception control unit 15, the DUT scanning control unit 16, the signal analysis control unit 17, the setting control unit 18a, the rotation speed management control unit 18b, the Reference position measurement control unit 18c, and the measurement status display control unit 18h are also realized by executing a predetermined program stored in the ROM 11b in the work area of the RAM 11c by the CPU 11a.

The call connection control unit 14 drives the test antenna 5 via the NR system simulator 20 and the signal processing unit 23 to transmit and receive a control signal (radio signal) to and from the DUT 100, thereby performing control to establish a call (a state where the radio signal can be transmitted and received) between the NR system simulator 20 and the DUT 100.

The signal transmission and reception control unit 15 performs a control of monitoring a user operation in the operation unit 12, transmitting a signal transmission command to the NR system simulator 20 after the call is established through call connection control, by being triggered with a predetermined measurement start operation related to the measurement of transmission and reception characteristics of the DUT 100 by the user, and transmitting the test signal from the NR system simulator 20 via the test antenna 5, and a control of transmitting a signal reception command and receiving the signal under measurement via the test antenna 5.

The DUT scanning control unit 16 drives and controls the drive motors 56f and 56g of the DUT scanning mechanism 56 to perform total spherical scanning of the DUT 100 mounted on the mounting tray 56d of the DUT mounting portion 56c.

Here, the total spherical scanning of the DUT 100 will be described with reference to FIGS. 5A and 5B to FIG. 7. Generally, related to power measurement of a signal radiated by the DUT 100 (radiated power measurement), a method for measuring an Equivalent Isotropic Radiated Power (EIRP) and a method for measuring Total Radiated Power (TRP) are known. The EIRP is, for example, a power value measured at each measurement point (θ, φ) in a spherical coordinate system (r, θ, φ) shown in FIG. 5A. On the other hand, the TRP is obtained by measuring the EIRP in all orientations of the spherical coordinate system (r, θ, φ), that is, at a plurality of angular sample points PS (refer to FIG. 5B), which are regulated in advance, on a spherical surface equidistant from a center O1 (hereinafter, a reference point) of the total spherical scanning of the DUT 100, and obtaining a total sum thereof.

In addition, regarding the reception sensitivity measurement, it is known to measure Equivalent Isotropic Sensitivity (EIS). The EIS is, for example, a reception sensitivity value measured at each measurement point (θ, φ) in a spherical coordinate system (r, θ, φ) shown in FIG. 5A.

The total spherical scanning of the DUT 100 means a control operation of sequentially changing the DUT 100 mounted on the mounting tray 56d in all orientations of a surface of a sphere B while using, for example, a center O1 of the sphere B (refer to FIGS. 5A and 5B) as a reference (center), that is, sequentially changing a posture of the DUT 100 in a state in which the antenna 110 faces the angular sample point PS.

In order to measure the EIRP or EIS at each angular sample point PS in accordance with the total spherical scanning of the DUT 100, as shown in FIG. 6, the test antenna 5 for receiving a signal radiated by the DUT 100 is disposed at a position of a specific angular sample point PS (one point) in the spherical coordinate system (r, θ, φ), as shown in FIG. 6.

In the total spherical scanning, the DUT 100 is driven (scanned) so that the antenna surface of the antenna 110 sequentially faces the light reception surface of the test antenna 5. As a result, the test antenna 5 can transmit and receive a signal for the TRP measurement to and from the antenna 110 of the DUT 100 on which the total spherical scanning is performed. Here, the transmitted and received signal is a test signal that is transmitted from the NR system simulator 20 via the test antenna 5, and a signal that is transmitted by the DUT 100, which has received the test signal, using the antenna 110, that is, a signal under measurement that is received via the test antenna 5.

The total spherical scanning of the DUT 100 is realized by rotationally driving the azimuth axis and the roll axis by the drive motors 56f and 56g which constitutes the DUT scanning mechanism 56. FIG. 7 shows a rotation drive image around the azimuth axis and the roll axis of the DUT scanning mechanism (biaxial positioner) 56 related to the total spherical scanning of the DUT 100 in the measurement device 1. As shown in FIG. 7, the DUT scanning mechanism 56 of the measurement device 1 according to the present embodiment moves the DUT 100 in an angular direction of o around the azimuth axis, for example, within a range of 180 degrees and moves the DUT 100 in an angular direction of θ around the roll axis, for example, within a range of 360 degrees, so that it is possible to perform the total spherical scanning (refer to FIGS. 5A and 5B and 6) in which the DUT 100 is rotated in all orientations based on the center O1 thereof.

In FIG. 7, Po indicates a unit movement angle in a total movement angle (180 degrees) in the rotation direction (angular direction of φ) of the azimuth axis, and θ₀ indicates the unit movement angle (hereinafter, step angle) in the total movement angle (360 degrees) in the rotation direction (angular direction of θ) of the roll axis. φ₀ and θ₀ are obtained by enabling, for example, the step angle having a desired value to be selectively set from a plurality of step angles having different values which are regulated in advance. The set φ₀ and θ₀ regulate an angle between the adjacent angular sample points PS shown in FIG. 5B, and, as a result, regulates the angular sample point PS, that is, the number of measurement positions.

In order to realize control of the total spherical scanning of the DUT 100 by the DUT scanning control unit 16, for example, a DUT scanning control table 16a is prepared in the ROM 11b in advance. The DUT scanning control table 16a stores, for example, coordinates of each angular sample point PS (refer to FIG. 5B) in the spherical coordinate system (refer to FIG. 5A) related to the total spherical scanning of the DUT 100, drive data of the drive motors 56f and 56g associated with the coordinates of each angular sample point PS, and control data associated with a stop time (measurement time) at each angular sample point PS. In a case where the drive motors 56f and 56g are, for example, stepping motors, for example, the number of drive pulses is stored as the drive data.

The ROM 11b is further prepared with a rotation speed management table 16b for managing rotation speeds of the drive motor 56f and the drive motor 56g of the DUT scanning mechanism 56. The rotation speed management table 16b manages the rotation speed of the drive motor 56g that rotationally drives the roll axis, and, more specifically, the rotation speed of the drive motor 56g in a case where the DUT scanning mechanism 56 is rotationally driven for each step angle.

Here, in a case where description is performed with reference to FIGS. 5A and 5B, the step angle indicates an angle between adjacent angular sample points PS (refer to FIG. 5B) in the spherical coordinate system (refer to FIG. 5A) related to the total spherical scanning. The angular sample point PS corresponds to the measurement position of the DUT 100, and the number thereof can be appropriately set to be variable according to a measurement item, a measurement condition, and the like. That is, the unit step angle is obtained by regulating an angle between adjacent measurement positions and may be variable according to the measurement item, the measurement condition, and the like. For the DUT scanning mechanism 56 according to the present embodiment, it is possible to selectively set, for example, a value of 1 degree (deg), 3 degrees, 5 degrees, 7.5 degrees, 10 degrees, 15 degrees, 30 degrees, and 90 degrees for the step angle θ (refer to FIG. 7) of the roll axis by the drive motor 56g.

The present embodiment is not limited thereto, instead of the rotation speed management table 16b (first rotation speed management table), a second rotation speed management table may be provided which manages a rotation speed of the drive motor 56f, which can minimize the movement time of the DUT scanning mechanism 56 in each step section to correspond to each step angle (corresponding to o in FIG. 7) of the azimuth axis, for example, 5 degrees, 10 degrees, 15 degrees, or 30 degrees.

Further, instead of the first rotation speed management table and the second rotation speed management table, a third rotation speed management table may be provided which manages the rotation speed of the drive motor 56g and the drive motor 56f, which can minimize the movement time of the DUT scanning mechanism 56 in each step section to correspond to each step angle θ of the roll axis and each step angle φ of the azimuth axis.

The DUT scanning control unit 16 expands the DUT scanning control table 16a into the work area of the RAM 11c, and drives and controls the drive motors 56f and 56g of the DUT scanning mechanism 56 based on the control data stored in the DUT scanning control table 16a. As a result, the total spherical scanning of the DUT 100 mounted on the DUT mounting portion 56c is performed. In the total spherical scanning, the antenna surface of the antenna 110 of the DUT 100 is stopped for a regulated time (the stop time) toward the angular sample point PS for each angular sample point PS in the spherical coordinate system, and, thereafter, an operation of moving to a next angular sample point PS (scanning of the DUT 100) is sequentially performed while targeting all the angular sample points PS.

Further, the DUT scanning control unit 16 performs rotation speed control on the drive motor 56g related to the movement of the DUT scanning mechanism 56 targeting each step angle θ of the roll axis using the rotation speed management table 16b under the control of the rotation speed management control unit 18b, which will be described later, in accordance with the total spherical scanning of the DUT scanning mechanism 56 using the DUT scanning control table 16a.

The signal analysis control unit 17 captures a radio signal, which is related to the NR and is received by the test antenna 5 in a case where the total spherical scanning of the DUT 100 is performed, via the NR system simulator 20, and performs an analysis process (measurement process) on the radio signal as a signal of a specific measurement item.

The setting control unit 18a is a functional unit for setting various information necessary to execute the rotation speed control of the drive motor 56f using the rotation speed management table 16b by the DUT scanning control unit 16. In a case where the specific measurement item is measured, the setting control unit 18a can selectively set a step angle of a desired value from among step angles (θ, φ) having a plurality of different values, for example, 5 degrees, 10 degrees, 15 degrees, and 30 degrees.

For example, the rotation speed management control unit 18b performs the rotation speed control of the drive motor 56f related to the movement of the DUT scanning mechanism 56 targeting each step angle θ of the roll axis in cooperation with the DUT scanning control unit 16 using the rotation speed management table 16b in accordance with the total spherical scanning of the DUT scanning mechanism 56 in a case where the TRP measurement is performed.

The Reference position measurement control unit 18c measures the output power of the DUT 100 at a Reference position, which is any preset measurement position, each time a certain period of time elapses in a case where the total spherical scanning of the DUT 100 is performed, and the Reference position measurement control unit 18c interrupts the measurement in a case where the output power is equal to or less than a preset regulated Power. In a case of interruption, the Reference position measurement control unit 18c excludes measurement data after the measurement at the previous Reference position from the measured value, and enables the measurement to be resumed from the excluded measurement position.

Therefore, the Reference position measurement control unit 18c includes a condition setting unit 18d, a Reference position measurement unit 18e, a power determination unit 18f, and an interrupt processing unit 18g.

The condition setting unit 18d sets the Reference position, a regulated time, which is the measurement time interval at the Reference position, a regulated Power, and the like.

The Reference position measurement unit 18e performs measurement at the Reference position each time the set regulated time elapses.

The Power determination unit 18f determines whether the output power of the DUT 100 measured by the Reference position measurement unit 18e is equal to or less than the regulated Power.

In a case where the measurement is interrupted due to the determination results by the Power determination unit 18f, the interrupt processing unit 18g performs interrupt processing such as interrupting the measurement, excluding the measurement data after the measurement at the previous Reference position from the measured value, and correcting the resumption position to resume the measurement from the excluded measurement position.

The measurement status display control unit 18h displays the progress of the measurement, the status of the measurement, and the like on the display unit 13.

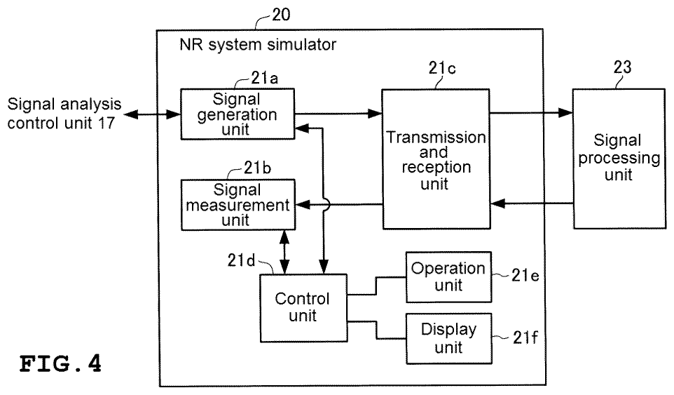

As shown in FIG. 4, the NR system simulator 20 includes a signal generation unit 21a, a signal measurement unit 21b, a transmission and reception unit 21c, a control unit 21d, an operation unit 21e, and a display unit 21f. The NR system simulator 20 constitutes a simulated measurement device of the present invention.

The signal generation unit 21a generates a signal (baseband signal) that becomes a source of the test signal. The transmission and reception unit 21c functions as an RF unit that generates the test signal corresponding to a frequency of each communication standard from the signal generated by the signal generation unit 21a and sends the generated test signal to the signal processing unit 23, and restores the baseband signal from the signal under measurement which is sent from the signal processing unit 23. The signal measurement unit 21b performs a measurement process of the signal under measurement based on the baseband signal restored by the transmission and reception unit 21c.

The control unit 21d comprehensively controls each of the functional units including the signal generation unit 21a, the signal measurement unit 21b, the transmission and reception unit 21c, the operation unit 21e, and the display unit 21f. The operation unit 21e is a functional unit for inputting various information such as commands, and the display unit 21f is a functional unit for displaying various information such as an input screen and measurement results of the various information.

In the measurement device 1 having the above-described configuration, the DUT 100 is mounted on the mounting tray 56d of the DUT scanning mechanism (biaxial positioner) 56 in the internal space 51 of the OTA chamber 50. Therefore, it is possible to perform measurement of the specific measurement item, such as measurement of the EIRP at each measurement position and measurement of the TRP over all measurement positions, while moving (rotating) the DUT 100 by a preset step angle in the biaxial (azimuth axis and roll axis) direction for each mounting tray 56d.

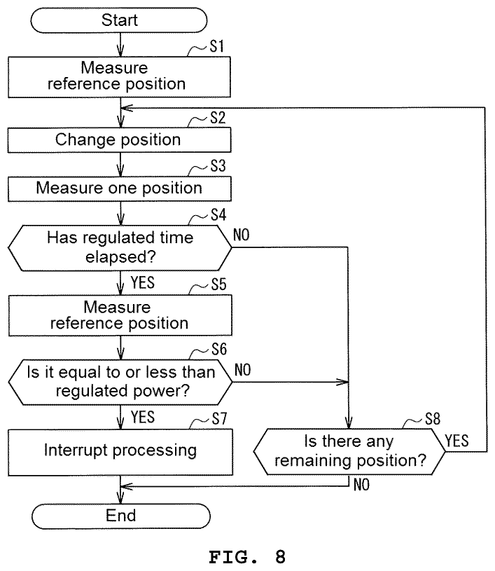

A measurement control operation when performing measurement of Spherical coverage by the integrated control device 10, which is performed in accordance with the total spherical scanning of the DUT 100 in the OTA chamber 50 of the measurement device 1, will be described with reference to the flowchart shown in FIG. 8.

In step S1, when the measurement start operation is performed by the operation on the operation unit 12, the control unit 11 performs measurement at the set Reference position. After executing the process of step S1, the control unit 11 executes the process of step S2.

In step S2, the control unit 11 changes the Position to the next measurement position. After executing the process of step S2, the control unit 11 executes the process of step S3.

In step S3, the control unit 11 performs measurement at one measurement position. After executing the process of step S3, the control unit 11 executes the process of step S4.

In step S4, the control unit 11 determines whether a regulated time has elapsed since the measurement at the previous Reference position.

When it is determined that the regulated time has elapsed, the control unit 11 executes the process of step S5. When it is determined that the regulated time has not elapsed, the control unit 11 executes the process of step S8.

In step S5, the control unit 11 performs measurement at the set Reference position. After executing the process of step S5, the control unit 11 executes the process of step S6.

In step S6, the control unit 11 determines whether the output power of the DUT 100 measured at the Reference position is equal to or less than the regulated Power.

When it is determined that the output power of the DUT 100 is equal to or less than the regulated Power, the control unit 11 executes the process of step S7. When it is determined that the output power of the DUT 100 is not equal to or less than the regulated Power, the control unit 11 executes the process of step S8.

In step S7, the control unit 11 performs interrupt processing such as interrupting the measurement, excluding the measurement data and correcting the resumption position. After executing the process of step S7, the control unit 11 ends the measurement control operation.

In step S8, the control unit 11 determines whether there is a remaining Position that is an unmeasured measurement position.

When it is determined that there is a remaining Position, the control unit 11 executes the process of step S2. When it is determined that there is no remaining position, the control unit 11 ends the measurement control operation.

As described above, in the above-described embodiment, the output power of the DUT 100 at the Reference position is measured each time a regulated time elapses, and in a case where the measured output power of the DUT 100 is equal to or less than the regulated Power, the measurement is interrupted, the measurement data after the measurement at the previous Reference position is excluded from the measured value, and the measurement is resumable from the excluded measurement position.

As a result, the measurement is performed at the Reference position each time the regulated time elapses, and in a case where the output power of the DUT 100 is equal to or less than the regulated Power, the measurement is interrupted, the measurement data after the measurement at the previous Reference position is excluded from the measured value, and the measurement is resumable from the excluded measurement position. Therefore, it is possible to improve the accuracy of measurement results by excluding the measurement data in which the output power of the DUT 100 is considered equal to or less than the regulated Power.

In addition, since the measurement is interrupted, it is possible to charge the DUT 100 or to lower the temperature of the DUT 100 during the interruption, thereby improving the test efficiency.

Hitherto, the embodiments of the present invention have been disclosed, but it is clear that changes can be made by those skilled in the art without departing from the scope of the present invention. All such modifications and equivalents are intended to be included in the claims as follows.

### DESCRIPTION OF REFERENCE NUMERALS AND SIGNS

1: Measurement device (mobile terminal testing device)
5: Test antenna
10: Integrated control device
16: DUT scanning control unit
18c: Reference position measurement control unit
18d: Condition setting unit
18e: Reference position measurement unit
18f: Power determination unit
18g: Interrupt processing unit
20: NR system simulator (simulated measurement device)
50: OTA chamber (anechoic box)
51: Internal space
56: DUT scanning mechanism (positioner)
56f, 56g: Drive motor
100: DUT (mobile terminal)

What is claimed is:

1. A mobile terminal testing device comprising:
a positioner that is provided in an internal space of an anechoic box, has an azimuth axis and a roll axis that are each rotationally drivable by a drive motor, and rotates a mobile terminal that is a device under test so that the mobile terminal sequentially faces a plurality of preset angular sample points of a spherical coordinate system, using a center of the spherical coordinate system as a reference point;
a simulated measurement device connected to a test antenna in the internal space;
an integrated control device that controls the simulated measurement device so that a measurement operation of transmitting a test signal from the test antenna to the mobile terminal, receiving a signal under measurement transmitted from the mobile terminal that has received the test signal by using the test antenna, and measuring a specific measurement item related to the mobile terminal based on the received signal under measurement is performed at a measurement position corresponding to each of the plurality of angular sample points; and
a Reference position measurement control unit that measures output power of the mobile terminal at a preset Reference position each time a preset regulated time elapses, and that, in a case where the measured output power is equal to or less than a preset regulated Power, interrupts the measurement, excludes measurement data after the measurement at a previous Reference position from a measured value, and enables the measurement to be resumed from the excluded measurement position.

2. A mobile terminal testing method of a mobile terminal testing device including a positioner that is provided in an internal space of an anechoic box, has an azimuth axis and a roll axis that are each rotationally drivable by a drive motor, and rotates a mobile terminal that is a device under test so that the mobile terminal sequentially faces a plurality of preset angular sample points of a spherical coordinate system, using a center of the spherical coordinate system as a reference point, a simulated measurement device connected to a test antenna in the internal space, and an integrated control device that controls the simulated measurement device so that a measurement operation of transmitting a test signal from the test antenna to the mobile terminal, receiving a signal under measurement transmitted from the mobile terminal that has received the test signal by using the test antenna, and measuring a specific measurement item related to the mobile terminal based on the received signal under measurement is performed at a measurement position corresponding to each of the plurality of angular sample points, the mobile terminal testing method comprising:
a step of measuring output power of the mobile terminal at a preset Reference position each time a preset regulated time elapses; and
a step of interrupting the measurement, excluding measurement data after the measurement at a previous Reference position from a measured value, and enabling the measurement to be resumed from the excluded measurement position, in a case where the measured output power is equal to or less than a preset regulated Power.
